(19) United States
(12) Patent Application Publication
(10) Pub. No.: US 2026/0256005 A1
(43) Pub. Date: Aug. 27, 2026

(54) Semiconductor Device and Method of Controlling Underfill Overflow

(71) Applicant: STATS ChipPAC Pte. Ltd., Singapore (SG)

(72) Inventors: Peik Eng Ooi, Singapore (SG); Beng Yee Teh, Singapore (SG)

(73) Assignee: STATS ChipPAC Pte. Ltd., Singapore (SG)

(21) Appl. No.: 19/062,402

(22) Filed: Feb. 25, 2025

(51) Int. Cl. H01L 23/00; H01L 21/78; H01L 25/065

(52) U.S. Cl. CPC H10W 72/30; H10W 72/073; H10W 72/20; H10W 99/00; H10P 54/00; H10W 72/072; H10W 72/07302; H10W 72/07353; H10W 72/331; H10W 72/387; H10W 72/851; H10W 74/15; H10W 90/00; H10W 90/722; H10W 90/732

(57) ABSTRACT

A semiconductor device has a substrate and interconnect structure formed over a die attach area of the substrate. An insulating layer is formed over a surface of the substrate. A trench is formed in the insulating layer between the die attach area and interconnect structure to extend around a perimeter of the die attach area. A semiconductor die is disposed over the die attach area. An underfill material is deposited under the semiconductor die. The trench prevents or impedes excess underfill material from reaching the interconnect structure. A T-bar structure is formed between the die attach area and interconnect structure to extend around a perimeter of the die attach area. The trench and/or T-bar structure operate as an overflow structure to impede the flow of the underfill material. A plurality of trenches and/or a plurality of T-bar structures can alternate around a perimeter of the die attach area.

### FIELD OF THE INVENTION

The present invention relates in general to semiconductor devices and, more particularly, to a semiconductor device and method of controlling underfill overflow.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor die and/or semiconductor wafers can be stacked for space efficiency. FIG. 1 illustrates a conventional semiconductor wafer or die 50 with conductive layer 52 and bumps 54. Semiconductor die 60 is mounted to semiconductor wafer/die 50 in die attach area 62 with bumps 64 connecting conductive layer 62 and contact pads 68. Semiconductor wafer/die 50 can be referred to as a mother die and semiconductor die 60 can be referred as a child die in a stacked arrangement. An underfill material 70 is deposited under semiconductor die 60 for structural support and environmental protection. The dispensing of underfill material 70 is typically difficult to control, depending on the manufacturing process. Excess underfill material 70 may bleed-out or otherwise overflow out from die attach area 62 and reach bumps 54 causing electrical isolation or short-circuit condition of the interconnect structures, depending on the underfill material, as well as other inspection and manufacturing defects.

### BRIEF DESCRIPTION OF THE DRAWINGS

FIG. 1 illustrates a conventional underfill overflow to nearby bumps;

FIGS. 2a-2f illustrate a semiconductor wafer with a plurality of semiconductor die separated by a saw street;

FIGS. 3a-3l illustrate a process of forming overflow structures as trenches between a die attach area and interconnect structures formed on a substrate;

FIGS. 4a-4f illustrate another process of forming overflow structures as T-bar structures between a die attach area and interconnect structures formed on a substrate;

FIG. 5 illustrates an embodiment with higher T-bar structures;

FIG. 6 illustrates an embodiment with a trench and T-bar structure;

FIGS. 7a-7b illustrates an embodiment with alternating trenches and T-bar structures; and

FIG. 8 illustrates a printed circuit board (PCB) with different types of packages disposed on a surface of the PCB.

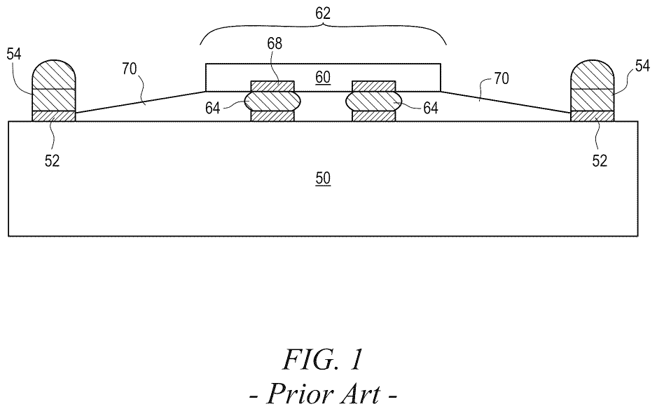

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

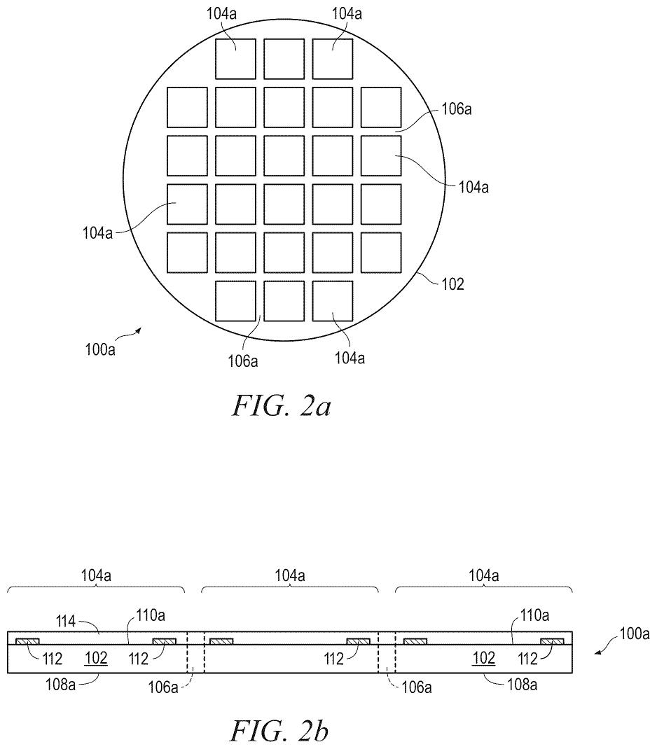

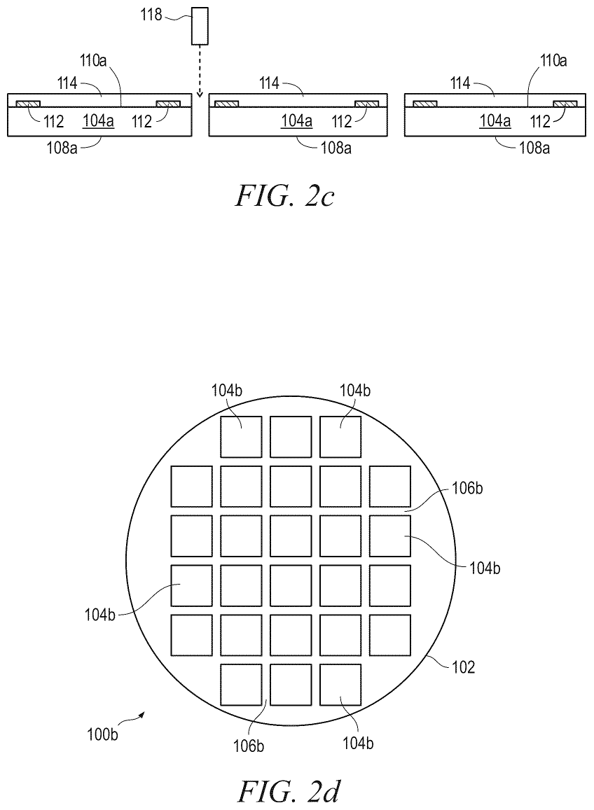

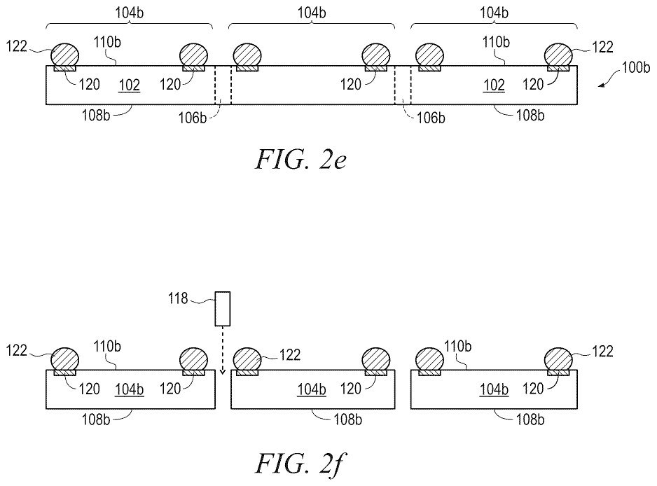

FIG. 2a shows a semiconductor wafer 100a with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104a is formed on wafer 100a separated by a non-active, inter-die wafer area or saw street 106a. Saw street 106a provides cutting areas to singulate semiconductor wafer 100a into individual semiconductor die 104a. In one embodiment, semiconductor wafer 100a is circular with a diameter of 100-450 millimeters (mm). Semiconductor wafer 100a can be rectangular or any other geometric shape.

FIG. 2b shows a cross-sectional view of a portion of semiconductor wafer 100a. Each semiconductor die 104a has a back or non-active surface 108a and an active layer 110a containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active layer 110 to implement analog circuits or digital circuits, such as digital signal processor (DSP), application specific integrated circuits (ASIC), memory, or other signal processing circuit. Semiconductor die 104a may also contain IPDs, such as inductors, capacitors, and resistors, for RF signal processing.

An electrically conductive layer 112 is formed over or within active layer 110a using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads or redistribution layer (RDL) electrically connected to the circuits in active layer 110a. Portions of conductive layer 112 can be electrically common or electrically isolated depending on the design and function of semiconductor die 104a within semiconductor wafer 100a and other electrical components.

An insulating or dielectric layer 114 is formed over active surface 110a and conductive layer 112 using PVD, CVD, printing, lamination, spin coating, spray coating, sintering or thermal oxidation. Insulating layer 114 contains one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties.

In FIG. 2c, semiconductor wafer 100a is singulated through saw street 106a using a saw blade or laser cutting tool 118 into individual semiconductor die 104a. The individual semiconductor die 104a can be inspected and electrically tested for identification of known good die or unit (KGD/KGU) post singulation.

In another case, FIG. 2d shows a semiconductor wafer 100b, made similar to semiconductor wafer 100a. A plurality of semiconductor die or components 104b is formed on wafer 100b separated by a non-active, inter-die wafer area or saw street 106b. Saw street 106b provides cutting areas to singulate semiconductor wafer 100b into individual semiconductor die 104b. In one embodiment, semiconductor wafer 100b is circular with a diameter of 100-450 mm. Semiconductor wafer 100 b can be rectangular or any other geometric shape.

FIG. 2e shows a cross-sectional view of a portion of semiconductor wafer 100b. Each semiconductor die 104b has a back or non-active surface 108b and an active layer 110b containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active layer 110 to implement analog circuits or digital circuits, such as DSP, ASIC, memory, or other signal processing circuit. Semiconductor die 104b may also contain IPDs, such as inductors, capacitors, and resistors, for RF signal processing. Semiconductor die 104b may have a different electrical function as semiconductor die 104a.

An electrically conductive layer 120 is formed over or within active layer 110b using PVD, CVD, electrolytic plating, electroless plating process, or other suitable metal deposition process. Conductive layer 120 can be one or more layers of Al, Cu, Sn, Ni, Au, Ag, or other suitable electrically conductive material. Conductive layer 120 operates as contact pads or RDL electrically connected to the circuits in active layer 110b.

An electrically conductive bump material is deposited over conductive layer 120 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 120 using a suitable attachment or bonding process. In one embodiment, the bump material is reflowed by heating the material above its melting point to form balls or bumps 122. In one embodiment, bump 122 is formed over an under bump metallization (UBM) having a wetting layer, barrier layer, and adhesive layer. Bump 122 can also be compression bonded or thermocompression bonded to conductive layer 120. Bump 122 represents one type of interconnect structure that can be formed over conductive layer 120. The interconnect structure can also use bond wires, conductive paste, stud bump, micro bump, or other electrical interconnect.

In FIG. 2f, semiconductor wafer 100b is singulated through saw street 106b using a saw blade or laser cutting tool 118 into individual semiconductor die 104b. The individual semiconductor die 104b can be inspected and electrically tested for identification of KGD/KGU post singulation.

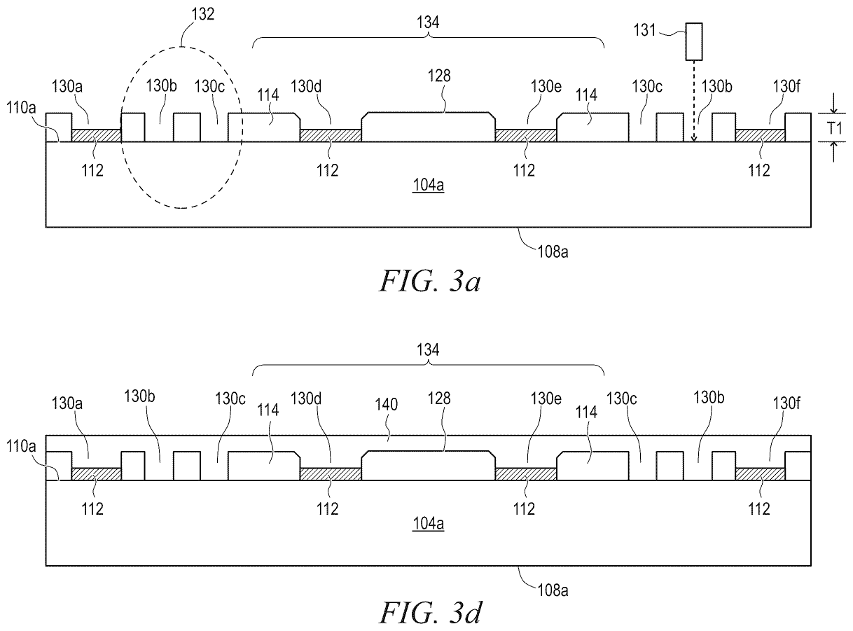

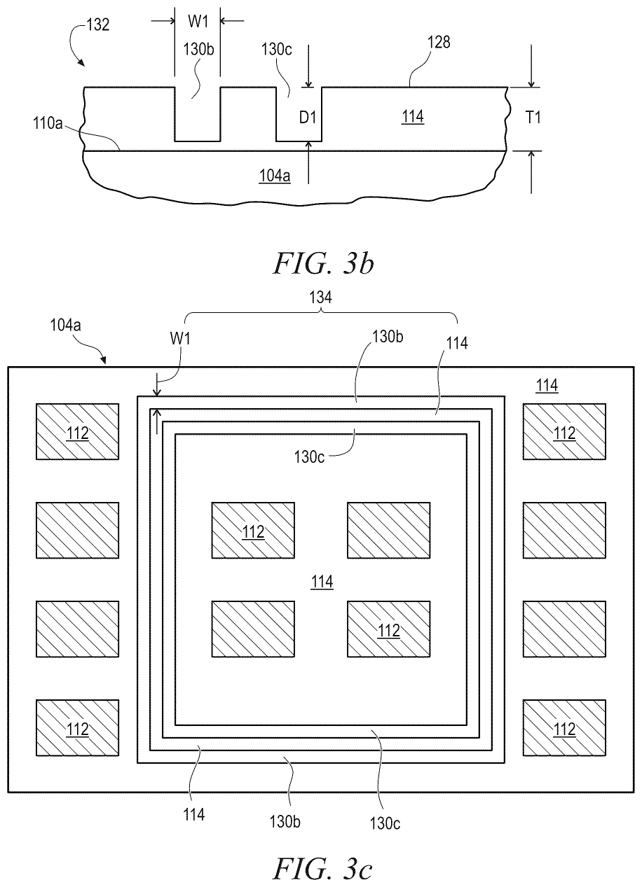

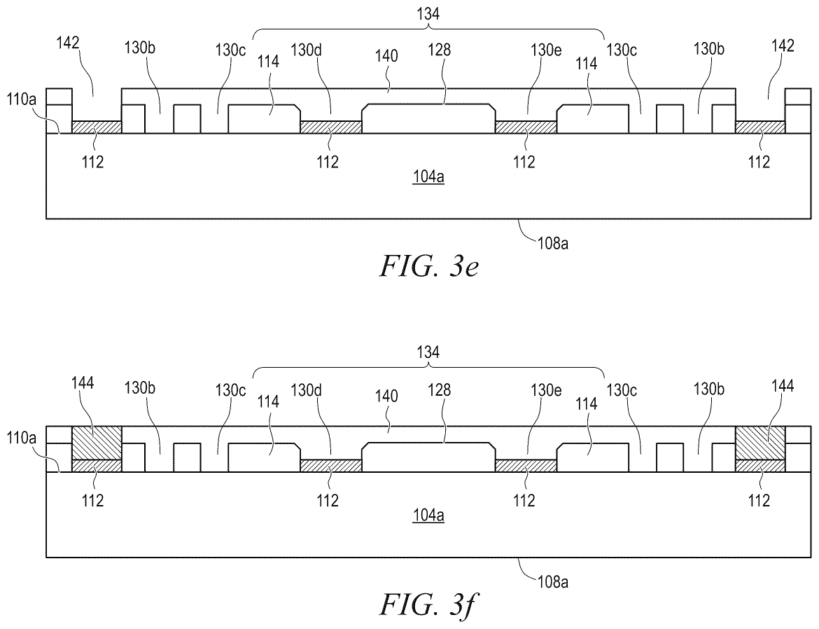

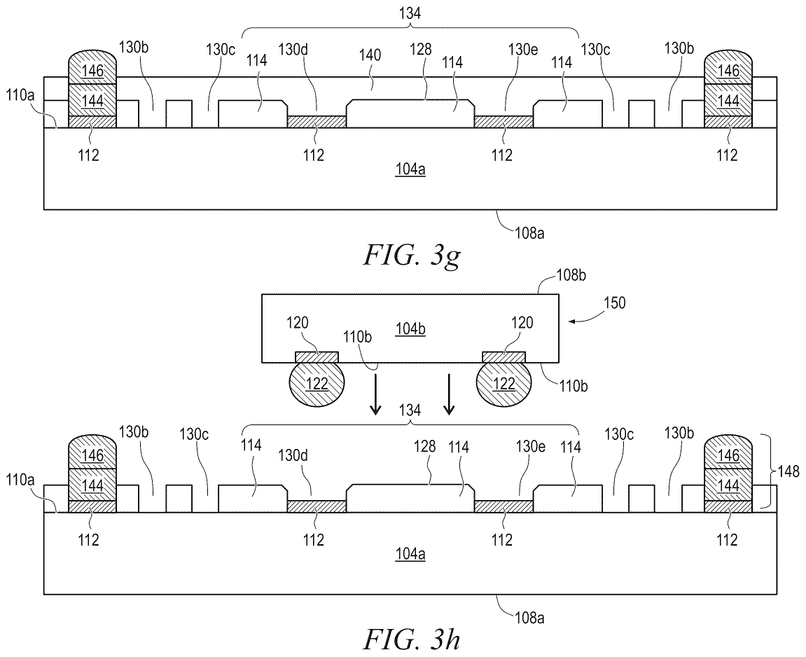

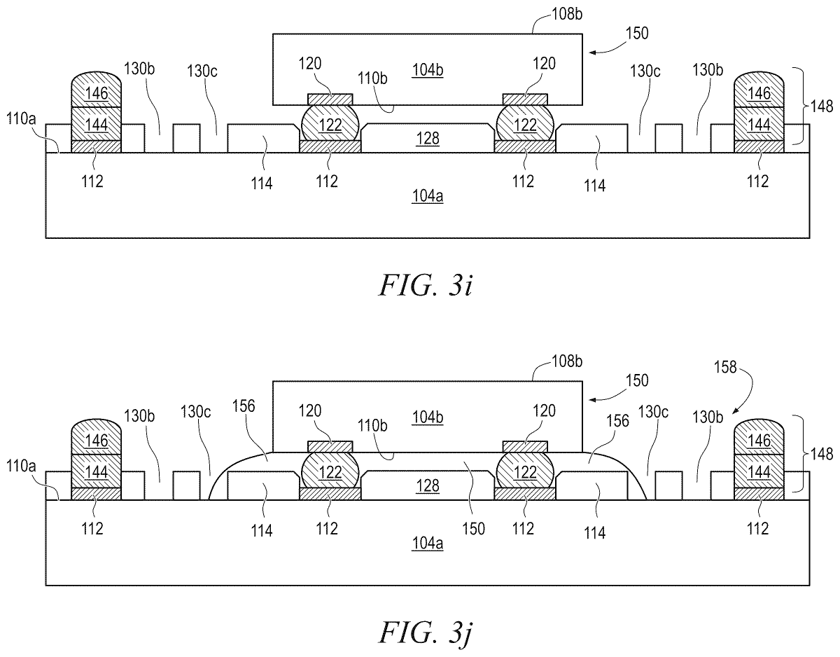

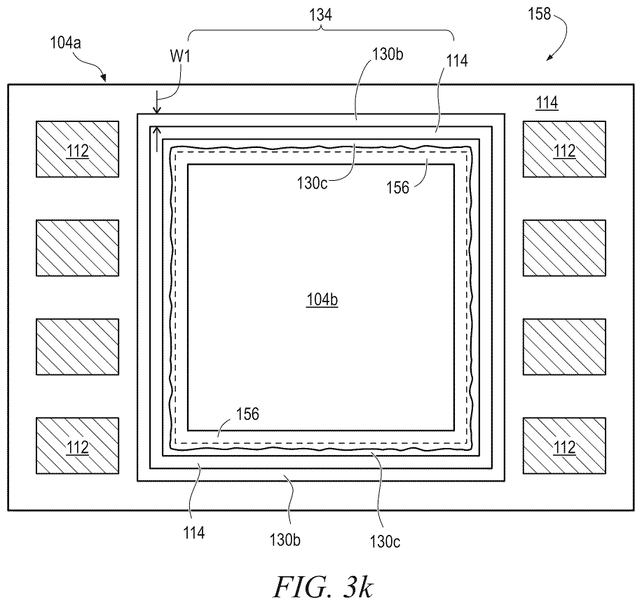

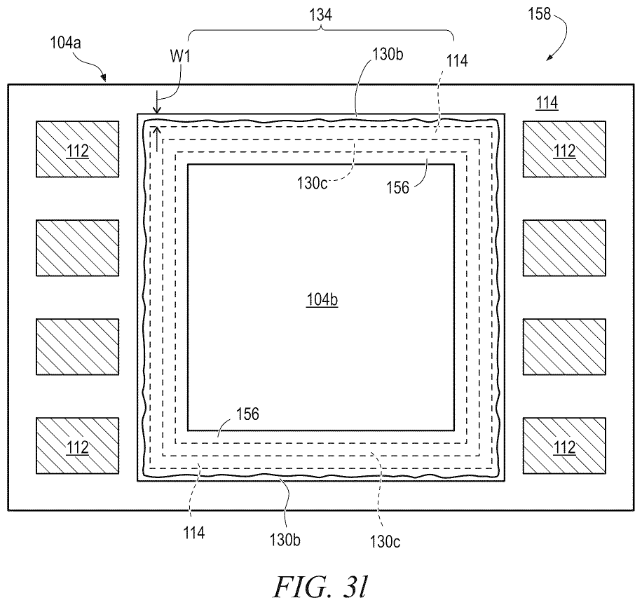

FIG. 3a shows further detail of a portion of semiconductor wafer 100a prior to singulation, or a portion of semiconductor die 104a post singulation. In one embodiment, insulating layer 114 has a thickness T1 of 10.0 micrometers (mm). A portion of insulating layer 114 is removed by an etching process or laser direct ablation (LDA) using laser 131 to form openings or trenches 130a-130f. Openings 130a, 130d, 130e, and 130f extend down to and expose conductive layer 112. The locations of openings 130a, 130d, 130e, and 130f are selected to align with conductive layer 112. Trenches 130b and 130c extend down into insulating layer 114 to active surface 110a, or to a level above the active surface. For example, FIG. 3b shows further detail of trenches 130b and 130c in region 132 extending to a depth D1 less than 10.0 mm and width W1 of at least 50.0 mm into insulating layer 114 above active surface 110a. FIG. 3c is a top view of semiconductor die 104a with openings 130a, 130d, 130e, and 130f exposing conductive layer 112 and trenches 130b and 130c extending around a circumference of die attach region 134. As will be shown, trenches 130b and 130c serve as an overflow structure to absorb, block, impede, or otherwise inhibit any overflow of underfill material from reaching other interconnect structures.

In FIG. 3d, photoresist layer 140 is deposited over semiconductor wafer 100a or semiconductor die 104a. In FIG. 3e, photoresist layer 140 is subject to LDA or patterned and etched over conductive layer 112 to form openings 142. In FIG. 3f, openings 142 in photoresist layer 140 are filled with electrically conductive material, such as Al, Cu, Sn, Ni, Au, Ag, or other suitable electrically conductive material, to form conductive pillars 144.

In FIG. 3g, an electrically conductive bump material is deposited over conductive pillars 144 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive pillars 144 using a suitable attachment or bonding process. In one embodiment, the bump material is reflowed by heating the material above its melting point to form balls or bumps 146. In one embodiment, bump 146 is formed over a UBM having a wetting layer, barrier layer, and adhesive layer. Bump 146 can also be compression bonded or thermocompression bonded to conductive pillars 144. Bump 146 represents one type of interconnect structure that can be formed over conductive pillars 144. The interconnect structure can also use bond wires, conductive paste, stud bump, micro bump, or other electrical interconnect. The combination of conductive pillar 144 and bumps 146 constitute vertical interconnect structure 148.

In FIG. 3h, photoresist layer 140 is removed leaving interconnect structures 148 over conductive layer 112 of semiconductor die 104a. One or more electrical components 150 are disposed over die attach area 134 using a pick and place operation with bumps 122 oriented toward conductive layer 112. In one embodiment, electrical component 150 can be semiconductor die 104b from FIG. 2f. Alternatively, electrical component 150 can include other semiconductor die, semiconductor packages, surface mount devices, discrete electrical devices, interconnect structures, or IPDs. In this case, semiconductor die 104a is considered the mother die, i.e., the larger semiconductor die, and semiconductor die 104b is considered the child die, i.e., smaller than semiconductor die 104a, in a stacked semiconductor arrangement. Semiconductor die 104a can have large dimensions on the order of 2.0×2.0 mm, while semiconductor die 104b can be smaller than semiconductor die 104a, typically on the order of 1.0×1.0 mm. FIG. 3 i shows electrical component 150 mounted to semiconductor die 104a with bumps 122 electrically and mechanically bonded to conductive layer 112 in die attach area 134.

In FIG. 3j, underfill material 156 is deposited under electrical component 150. The dispensing of underfill material 156 can be difficult to control. Any excess underfill material 156 flows outward from the perimeter of electrical component 150. Underfill material 156 should not be allowed to reach interconnect structure 148, as that event could cause defects. As underfill material 156 reaches trench 130c, the trench operates as an overflow structure to absorb, block, impede, or otherwise inhibit further progression of the underfill material. That is, excess underfill material 156 flows into trench 130c and stops the outward flow of the underfill material toward interconnect structure 148. FIG. 3k shows a top view of trenches 130b and 130c disposed around the circumference of electrical component 150 in order to surround all sides of the electrical component. Underfill material 156 is shown impeded by trench 130c in stacked semiconductor package 158.

If the capacity of trench 130c is insufficient to stop the outward flow of underfill material 156, then trench 130b operates as a secondary overflow structure to provide the next layer of protection to absorb, block, impede, or otherwise inhibit further progression of the underfill material. As underfill material 156 reaches trench 130b, the trench operates as a secondary overflow structure to absorb, block, impede, or otherwise inhibit further progression of the underfill material. That is, excess underfill material 156 flows into trench 130b and stops the outward flow of the underfill material toward interconnect structure 148. FIG. 3l shows a top view of underfill material 156 impeded by trench 130b.

Trenches 130b and 130c control the overflow of excess underfill material 156 bleeding out from under semiconductor die 104b. The present embodiment shows two trenches 103b and 130c. There may be only one trench or there may be more than two trenches. In any case, depending on the control of underfill material 156, one or more trenches are disposed around a circumference of die attach area 134 and electrical component 150 to prevent or impede the underfill material from reaching interconnect structure 148.

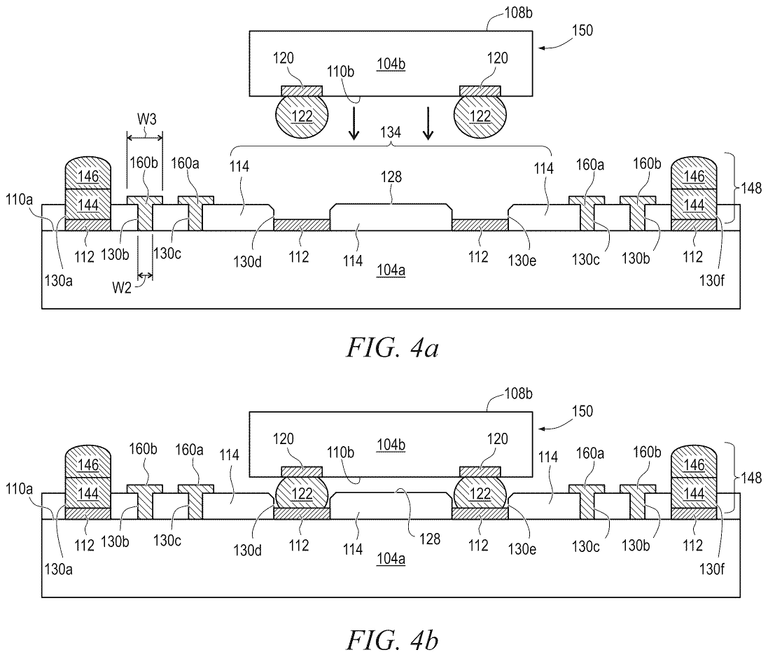

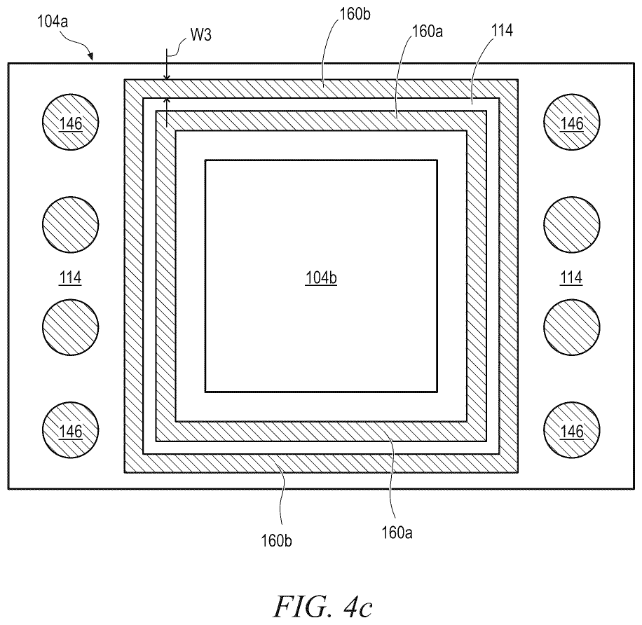

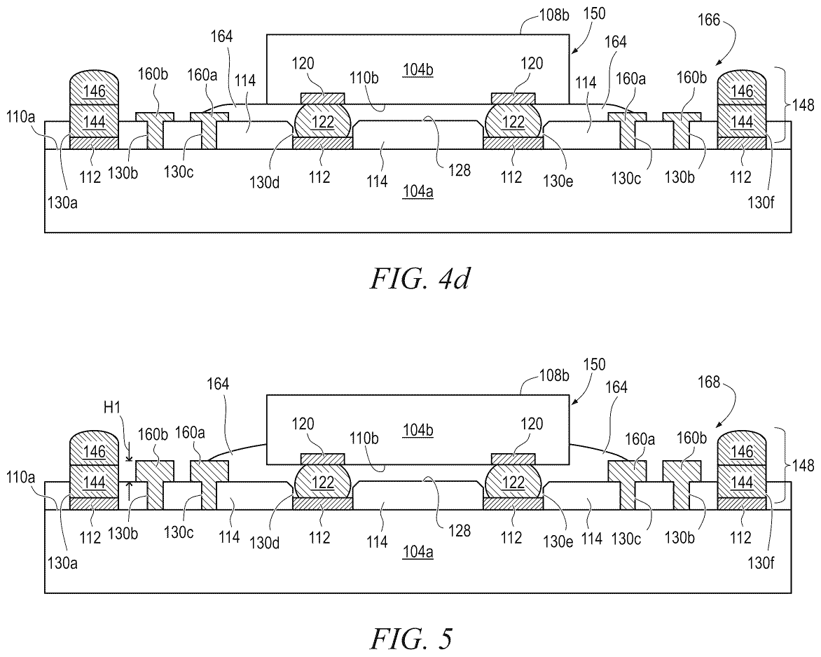

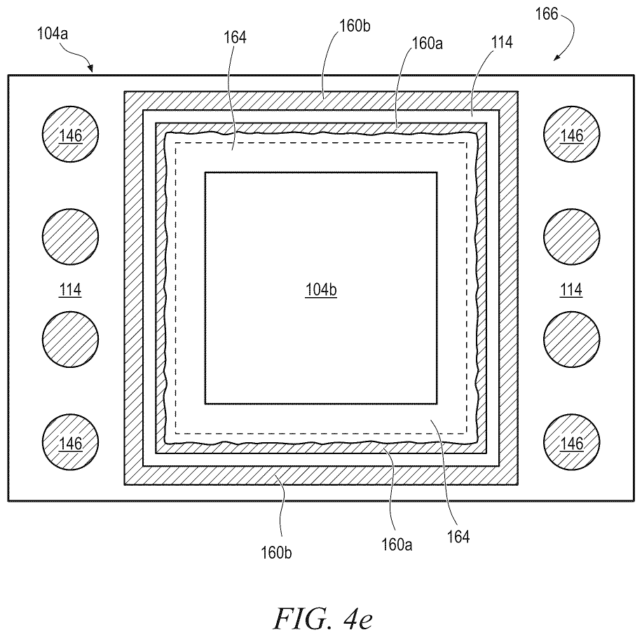

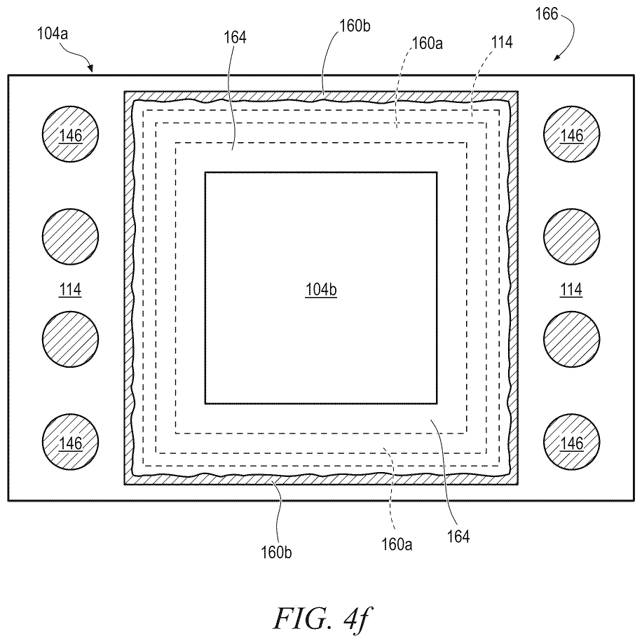

In another embodiment, continuing from FIG. 3h, trenches 130b and 130c are filled with solid material, such as metal, polymer, or epoxy, to form T-bar structures 160a and 160b, as shown in FIG. 4a. Components having a similar function are assigned the same reference numbers. Trenches 130b and 130c may have a width W2 of at least 20.0 mm. T-bar structures 160a-160b have a width W3 on the order of at least 30.0 mm.

One or more electrical components 150 are disposed over die attach area 134 using a pick and place operation with bumps 122 oriented toward conductive layer 112. In one embodiment, electrical component 150 can be semiconductor die 104b from FIG. 2f. Alternatively, electrical component 150 can include other semiconductor die, semiconductor packages, surface mount devices, discrete electrical devices, interconnect structures, or IPDs. In this case, semiconductor die 104a is considered the mother die, i.e., the larger semiconductor die, and semiconductor die 104b is considered the child die, i.e., smaller than semiconductor die 104a, in a stacked arrangement. FIG. 4b shows electrical component 150 mounted to semiconductor die 104a with bumps 122 electrically and mechanically bonded to conductive layer 112 in die attach area 134.

FIG. 4c is a top view of semiconductor die 104a with bumps 146 of interconnect structure 148 and T-bar structures 160a and 160b extending around a circumference of die attach region 134. T-bar structures 160a and 160b can be formed in the same photomask as conductive layer 112, i.e., prior to forming interconnect structure 148. As will be shown, T-bar structures 160a and 160b serve as an overflow structure to absorb, block, impede, or otherwise inhibit any overflow of underfill material from reaching interconnect structures 148.

In FIG. 4d, underfill material 164 is deposited under electrical component 150. The dispensing of underfill material 164 can be difficult to control. Any excess underfill material 164 flows outward from the perimeter of electrical component 150. Underfill material 164 should not be allowed to reach interconnect structure 148, as that event could cause defects. As underfill material 164 reaches T-bar structure 160a, the T-bar structure operates as an overflow structure to absorb, block, impede, or otherwise inhibit further progression of the underfill material. That is, excess underfill material 164 flows up against T-bar structure 160a, and possibly over its top surface, to stop the outward flow of the underfill material toward interconnect structure 148 in stacked semiconductor package 166. FIG. 4e shows a top view of T-bar structures 160a and 160b disposed around the circumference of electrical component 150 in order to surround all sides of the electrical component. Underfill material 164 is shown impeded by T-bar structure 160a in stacked semiconductor package 166.

If the capacity of T-bar structure 160a is insufficient to stop the outward flow of underfill material 164, then T-bar structure 160b operates as a secondary overflow structure to provide the next layer of protection to absorb, block, impede, or otherwise inhibit further progression of the underfill material. As underfill material 164 reaches T-bar structure 160b, the T-bar structure operates as a secondary overflow structure to absorb, block, impede, or otherwise inhibit further progression of the underfill material. That is, excess underfill material 164 flows up against T-bar structure 160a, and possibly over its top surface, to stop the outward flow of the underfill material toward interconnect structure 148. FIG. 4f shows underfill material 164 impeded by T-bar structure 160b.

T-bar structures 160a and 160b control the overflow of excess underfill material 164 bleeding out from under semiconductor die 104b. The present embodiment shows two T-bar structures 160a and 160b. There may be only one T-bar structure or there may be more than two T-bar structures. In any case, depending on the control of underfill material 164, one or more T-bar structures are disposed around a circumference of die attach area 134 and electrical component 150 to prevent or impede the underfill material from reaching interconnect structure 148.

In another embodiment, continuing from FIG. 4d, trenches 130b and 130c are filled with solid material, such as metal, polymer, or epoxy, to form T-bar structures 160a and 160b, as shown in FIG. 5. In this case, T-bar structures 160a and 160 a have a height H1 above surface 128 of at least 20.0 mm, greater than shown in FIG. 4d. T-bar structures 160a and 160b in FIG. 5 operate as overflow structures to absorb, block, impede, or otherwise inhibit further progression of the underfill material in stacked semiconductor package 168, similar to FIGS. 4d-4f. T-bar structures 160a and 160b can be formed in the same photomask as conductive layer 112, i.e., prior to forming interconnect structure 148.

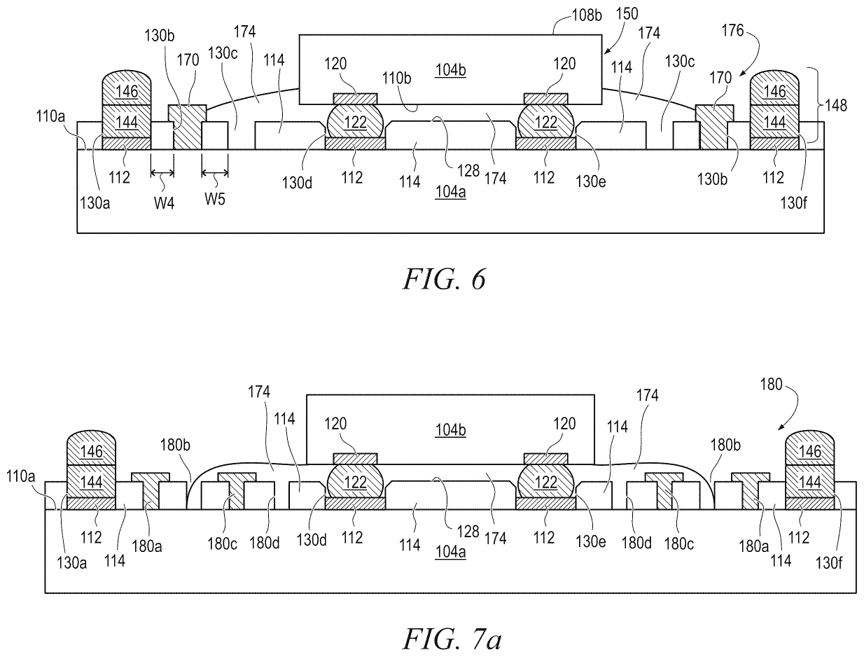

In another embodiment, continuing from FIG. 3i, trench 130b is filled with solid material, such as metal, polymer, or epoxy, to form T-bar structure 170, as shown in FIG. 6. Trench 130c remains open. Alternatively, trench 130c is filled with solid material, such as metal, polymer, or epoxy, to form T-bar structure 170, and trench 130b remains open. T-bar structure 170 can be formed in the same photomask as conductive layer 112, i.e., prior to forming interconnect structure 148.

An underfill material 174 is deposited under electrical component 150, similar to FIG. 4d. The dispensing of underfill material 174 can be difficult to control. Any excess underfill material 174 flows outward from the perimeter of electrical component 150. Underfill material 174 should not be allowed to reach interconnect structure 148, as that event could cause defects. As underfill material 174 reaches trench 130c, the trench operates as an overflow structure to absorb, block, impede, or otherwise inhibit further progression of the underfill material. That is, excess underfill material 174 flows into trench 130c and stops the outward flow of the underfill material toward interconnect structure 148 in stacked semiconductor package 176.

If the capacity of trench 130c is insufficient to stop the outward flow of underfill material 174, then T-bar structure 170 operates as an overflow structure to provide the next layer of protection to absorb, block, impede, or otherwise inhibit further progression of the underfill material. As underfill material 174 reaches T-bar structure 170, the T-bar structure operates as an overflow structure to absorb, block, impede, or otherwise inhibit further progression of the underfill material. That is, excess underfill material 164 flows up against T-bar structure 170, and possibly over its top surface, to stop the outward flow of the underfill material toward interconnect structure 148 in stacked semiconductor package 176, similar to FIGS. 3k-3l and 4e-4f.

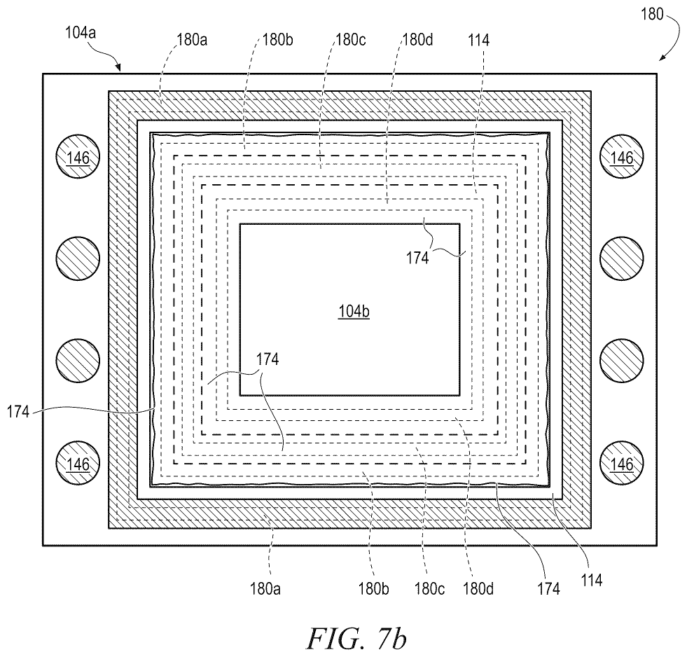

Trench 130c and T-bar structure 170 control the overflow of excess underfill material 174 bleeding out from under semiconductor die 104b. The present embodiment shows one trench 130c and one T-bar structure 170. There may be any combination of trenches and T-bar structures. For example, FIG. 7a shows T-bar structure 180a, trench 180b, T-bar structure 180c, and trench 180d alternating between die attach area 134 and interconnect structures 148. T-bar structures 180a and 180c can be formed similar to T-bar structure 160a-160b. T-bar structures 180a and 180c can be formed in the same photomask as conductive layer 112, i.e., prior to forming interconnect structure 148. In any case, depending on the control of underfill material 174, one or more trenches one or more T-bar structures are disposed around a circumference of die attach area 134 and electrical component 150, and possibly alternating in arrangement, to impede the underfill material from reaching interconnect structure 148 in stacked semiconductor package 180. FIG. 7b shows a top view of excess underfill material 174 stopping between trench 180b and T-bar structure 180a in stacked semiconductor package 180.

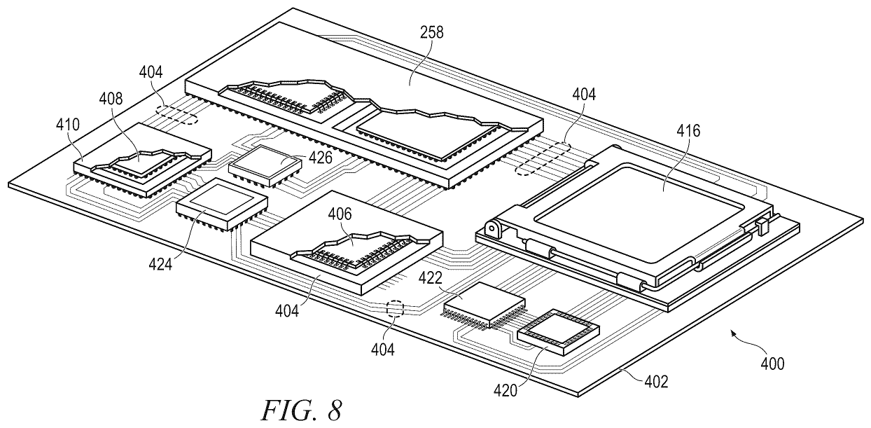

FIG. 8 illustrates electrical device 400 having a chip carrier substrate or PCB 402 with a plurality of semiconductor packages disposed on a surface of PCB 402, including stacked semiconductor packages 158, 166, 168, 176, and 180. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 8, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may have the first level packaging where the die is mechanically and electrically disposed directly on the PCB.

For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
a substrate including a die attach area;
an interconnect structure formed over the substrate;
a trench formed between the die attach area and interconnect structure;
a semiconductor die disposed over the die attach area; and
an underfill material deposited under the semiconductor die, wherein the trench prevents excess underfill material from reaching the interconnect structure.

2. The semiconductor device of claim 1, further including an insulating layer formed over a surface of the substrate, wherein the trench is formed in the insulating layer.

3. The semiconductor device of claim 1, wherein the trench extends around a perimeter of the die attach area.

4. The semiconductor device of claim 1, further including a T-bar structure formed between the die attach area and interconnect structure.

5. The semiconductor device of claim 4, wherein the T-bar structure extends around a perimeter of the die attach area.

6. The semiconductor device of claim 1, further including a plurality of trenches and a plurality of T-bar structures alternating around a perimeter of the die attach area.

7. A semiconductor device, comprising:
a substrate;
an overflow structure formed around a die attach area of the substrate;
a semiconductor die disposed over the die attach area; and
an underfill material deposited under the semiconductor die, wherein the overflow structure impedes the underfill material.

8. The semiconductor device of claim 7, further including an insulating layer formed over a surface of the substrate.

9. The semiconductor device of claim 8, wherein the overflow structure includes a trench formed in the insulating layer around the die attach area.

10. The semiconductor device of claim 7, wherein the overflow structure is disposed around a perimeter of the die attach area.

11. The semiconductor device of claim 7, wherein the overflow structure further includes a T-bar structure formed around the die attach area.

12. The semiconductor device of claim 7, further including an interconnect structure formed over the substrate, wherein the overflow structure prevents excess underfill material from reaching the interconnect structure.

13. The semiconductor device of claim 7, wherein the overflow structure further includes a plurality of trenches and a plurality of T-bar structures alternating around a perimeter of the die attach area.

14. A method of making a semiconductor device, comprising:
providing a substrate including a die attach area;
forming an interconnect structure over the substrate;
forming an overflow structure between the die attach area and interconnect structure;
disposing a semiconductor die over the die attach area; and
depositing an underfill material under the semiconductor die, wherein the overflow structure impedes excess underfill material from reaching the interconnect structure.

15. The method of claim 14, further including forming an insulating layer over a surface of the substrate.

16. The method of claim 15, wherein forming the overflow structure includes forming a trench in the insulating layer around the die attach area.

17. The method of claim 14, wherein the overflow structure extends around a perimeter of the die attach area.

18. The method of claim 14, wherein forming the overflow structure further includes forming a T-bar structure around the die attach area.

19. The method of claim 14, wherein forming the overflow structure further includes forming a plurality of trenches and a plurality of T-bar structures alternating around a perimeter of the die attach area.

20. A method of making a semiconductor device, comprising:
providing a substrate;
forming an overflow structure around a die attach area of the substrate;
disposing a semiconductor die over the die attach area; and
depositing an underfill material under the semiconductor die, wherein the overflow structure impedes the underfill material.

21. The method of claim 20, further including forming an insulating layer over a surface of the substrate.

22. The method of claim 21, wherein forming the overflow structure includes forming a trench in the insulating layer around the die attach area.

23. The method of claim 20, wherein forming the overflow structure further includes forming a T-bar structure around the die attach area.

24. The method of claim 20, wherein the overflow structure extends around a perimeter of the die attach area.

25. The method of claim 20, wherein forming the overflow structure further includes forming a plurality of trenches and a plurality of T-bar structures alternating around a perimeter of the die attach area.
